(19) United States
(12) Patent Application Publication
(10) Pub. No.: US 2024/0234150 A1
(43) Pub. Date: Jul. 11, 2024

(54) METHOD OF MANUFACTURING DISPLAY DEVICE

(71) Applicant: SAMSUNG DISPLAY CO., LTD., Yongin-si, Gyeonggi-do (KR)

(72) Inventors: YOUNGJIN OH, Yongin-si (KR); JINHYEONG KIM, Yongin-si (KR); HO YUN KANG, Yongin-si (KR); SANG-PIL PARK, Yongin-si (KR); KYUNG CHUL SHIN, Yongin-si (KR); DONGKEUN LEE, Yongin-si (KR); GIHAN LEEM, Yongin-si (KR); HEE-CHEOL IM, Yongin-si (KR); JAEJIN PYUN, Yongin-si (KR)

(21) Appl. No.: 18/540,733

(22) Filed: Dec. 14, 2023

(30) Foreign Application Priority Data
Jan. 6, 2023 (KR) 10-2023-0002363

(51) Int. Cl. H01L 21/268

(52) U.S. Cl. CPC H01L 21/268

(57) ABSTRACT

A method of manufacturing a display device includes preparing a processing target including a first layer, a second layer, and a third layer located between the first layer and the second layer and having an absorptance that is smaller than each of an absorptance of the first layer and an absorptance of the second layer, and sequentially removing the first layer and the second layer by irradiating a pulsed laser beam to the processing target.

### CROSS-REFERENCE TO RELATED APPLICATION

This application claims priority to and the benefit of Korean Patent Application No. 10-2023-0002363, filed on Jan. 6, 2023 in the Korean Intellectual Property Office, the entire content of which is herein incorporated by reference.

### BACKGROUND

### 1. Field

Aspects of embodiments of the present disclosure relate to a method of manufacturing a display device.

### 2. Description of the Related Art

A laser beam may be used in various ways in a manufacturing process of a display device. For example, the laser beam may be used in various manufacturing processes of the display device, such as an annealing process, a cutting process, a welding process, and a bleaching process and the like.

The display device may be a device configured to visually display data. The display device may include a cell substrate partitioned into a display area and a non-display area.

A plurality of pixel areas may be defined in the display area. Each of the pixel areas may include at least one transistor and a pixel electrode electrically connected to the transistor. The non-display area may include a plurality of lines capable of transmitting electrical signals to the display area.

### SUMMARY

According to an aspect of embodiments of the present disclosure, a method of manufacturing a display device using a laser is provided. According to another aspect of embodiments of the present disclosure, a method of manufacturing a display device including a multi-layer structure having different optical properties is provided.

According to one or more embodiments, a method of manufacturing a display device includes preparing a processing target and sequentially removing a first layer and a second layer. The processing target may include the first layer, the second layer, and a third layer. The third layer may be disposed or located between the first layer and the second layer and have an absorptance that is smaller than each of an absorptance of the first layer and an absorptance of the second layer. The first layer and the second layer may be sequentially removed by irradiating a pulsed laser beam to the processing target.

In an embodiment, the preparing of the processing target may include preparing the third layer including a glass and forming the first layer and the second layer each including a colored ink on upper and lower portions of the third layer.

In an embodiment, the sequentially removing of the first layer and the second layer may include selectively removing a portion of the colored ink included in the first layer and the second layer by using the laser beam.

In an embodiment, the preparing of the processing target may include forming the third layer including a display panel including a display area, a pad area spaced apart from the display area, and a bending area located between the display area and the pad area, and an adhesive layer on the display panel, forming the first layer including a polarization layer on the third layer, and forming the second layer including a lower protective film under the third layer.

In an embodiment, the sequentially removing the first layer and the second layer may include selectively removing only a portion of the polarization layer and a portion of the lower protective film which overlap the bending area of the display panel by using the laser beam.

In an embodiment, the display panel may be formed on a substrate including polyimide, the adhesive layer may be formed of a pressure-sensitive adhesive, the polarization layer may be formed of polyvinyl alcohol, and the lower protective film may be formed of polyethylene terephthalate.

In an embodiment, the pulsed laser beam may have a pulse width of nanosecond scale or less.

In an embodiment, each of the absorptance of the first layer and the absorptance of the second layer may be greater than or equal to about 5 percent, and the absorptance of the third layer may be less than or equal to about 0.5 percent.

According to one or more embodiments, a method of manufacturing a display device includes preparing a processing target including a first layer and a second layer disposed or located under the first layer and having a refractive index that is greater than a refractive index of the first layer, and processing the first layer by irradiating a pulsed laser beam having a pulse width of nanosecond scale or less to the processing target.

In an embodiment, the preparing of the processing target may include forming the second layer including a display panel including a display area, a pad area spaced apart from the display area, and a bending area located between the display area and the pad area, and an adhesive layer on the display panel, and forming the first layer including an upper protective film on the second layer.

In an embodiment, the processing of the first layer may include selectively removing only a portion of the upper protective film which overlaps the bending area of the display panel by using the pulsed laser beam.

In an embodiment, the display panel may be formed on a substrate including polyimide, the adhesive layer may be formed of a pressure-sensitive adhesive, and the upper protective film may be formed of polyethylene terephthalate.

In an embodiment, the preparing of the processing target may include forming the second layer including a metal, and forming a first preliminary layer including a polymer compound and having a plate shape.

In an embodiment, the processing the first layer may include forming a concavo-convex shape by irradiating the laser beam to the first preliminary layer.

In an embodiment, the metal may include at least one selected from the group consisting of silver, molybdenum, copper, aluminum, titanium, and chromium, and the polymer compound may include at least one selected from the group consisting of polyimide, polyethylene terephthalate, and silicon oxide.

In an embodiment, the preparing the processing target may include forming the second layer including a display panel including a display area, a pad area spaced apart from the display area, and a bending area located between the display area and the pad area, and an adhesive layer on the display panel, and forming the first layer including a polarization layer on the second layer.

In an embodiment, the processing of the first layer may include selectively removing only a portion of the polarization layer which overlaps the bending area of the display panel by using the pulsed laser beam.

In an embodiment, the display panel may be formed on a substrate including polyimide, the adhesive layer may be formed of a pressure-sensitive adhesive, and the polarization layer may be formed of polyvinyl alcohol.

In the method of manufacturing the display device according to embodiments of the disclosure, processing for preserving the optical properties of a layer having a relatively low absorptance may be performed using a difference in absorptance.

In addition, the manufacturing method of the display device may perform the processing to preserve the optical properties of the layer having a relatively high refractive index by using a difference in refractive index.

In addition, in the manufacturing method of the display device, adhesive forces of an interface between layers having the different optical properties may be adjusted by changing a spot radius of the laser beam.

### BRIEF DESCRIPTION OF THE DRAWINGS

FIGS. 1 and 2 are perspective views illustrating a display device according to an embodiment of the disclosure.

FIG. 3 is an exploded perspective view illustrating a display device according to an embodiment of the disclosure.

FIG. 4 is a plan view illustrating a display panel included in the display device of FIG. 3.

FIG. 5 is a cross-sectional view illustrating the display panel included in the display device of FIG. 3.

FIGS. 6 to 13 are cross-sectional views illustrating a method of manufacturing a display device according to an embodiment of the disclosure.

FIGS. 14 to 22 are cross-sectional views illustrating a method of manufacturing a display device according to another embodiment of the disclosure.

FIG. 23 is a view illustrating a method of manufacturing a display device according to another embodiment of the disclosure.

### DETAILED DESCRIPTION

Herein, some embodiments of the present invention will be described in further detail with reference to the accompanying drawings. The same reference numerals are used for the same components in the drawings, and redundant descriptions of the same components may be omitted.

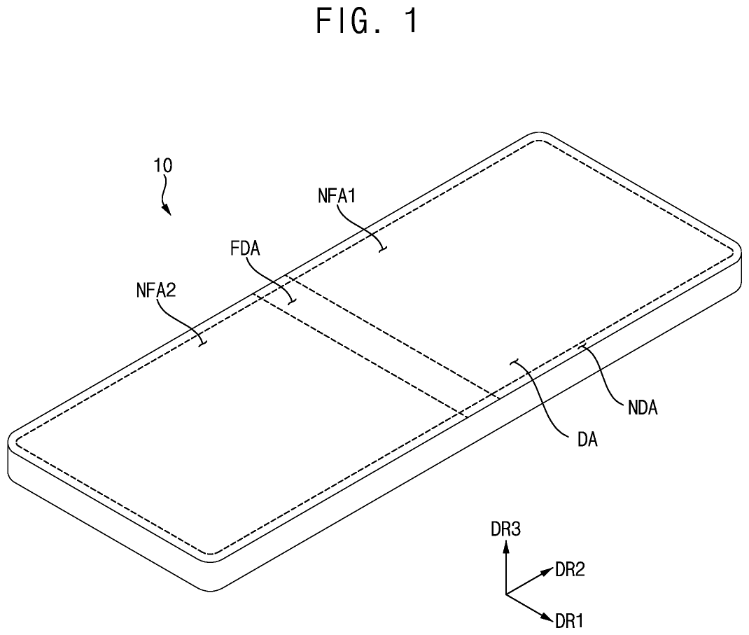

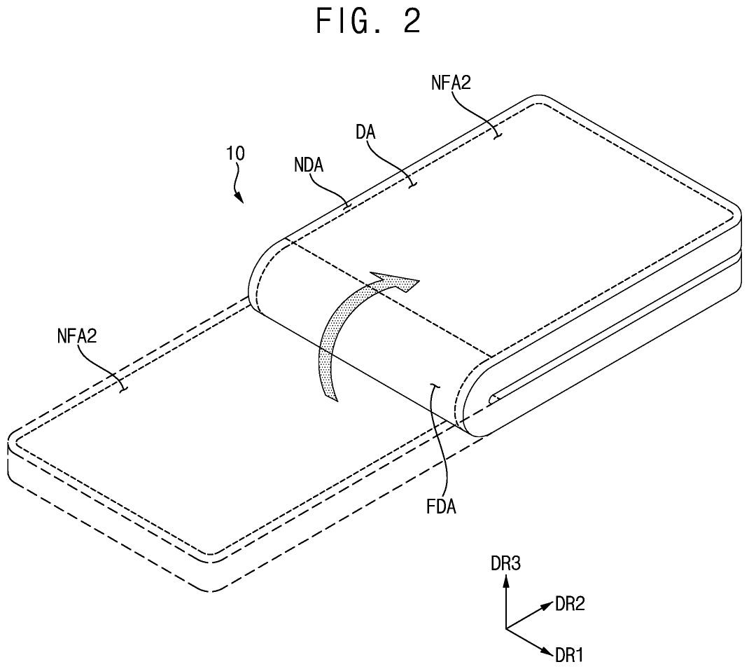

FIGS. 1 and 2 are perspective views illustrating a display device according to an embodiment of the disclosure.

For example, FIG. 1 is a perspective view showing a display device 10 in an unfolded state, and FIG. 2 is a perspective view showing the display device 10 in a folded state.

Referring to FIGS. 1 and 2, the display device 10 may include a display area DA and a non-display area NDA.

The display area DA may be an area capable of displaying an image by generating light. A plurality of pixels that emits the light may be disposed in the display area DA. Accordingly, the image may be displayed on the display area DA. In an embodiment, the plurality of pixels may be arranged in a matrix form along a first direction DR1 and a second direction DR2. The second direction DR2 may cross the first direction DR1. For example, the second direction DR2 may be perpendicular to the first direction DR1. In this case, the image may be displayed on the display area DA in a third direction DR3. The third direction DR3 may be perpendicular to each of the first and second directions DR1 and DR2.

The non-display area NDA may be an area not displaying the image. In an embodiment, the non-display area NDA may surround at least a portion of the display area DA. For example, the non-display area NDA may entirely surround the display area DA.

In an embodiment, the display device 10 may be a foldable display device. The display device 10 may include a first non-folding area NFA1, a second non-folding area NFA2, and a folding area FDA according to whether the display device 10 is folded. The first non-folding area NFA1 and the second non-folding area NFA2 may be spaced apart from each other, and the folding area FDA may be positioned between the first non-folding area NFA1 and the second non-folding area NFA2.

The folding area FDA may be an area where the display device 10 is folded. Each of the first non-folding area NFA1 and the second non-folding area NFA2 may be an area where the display device 10 is not folded. The first non-folding area NFA1 and the second non-folding area NFA2 may face each other by folding the display device 10 based on the folding area FDA. The folding area FDA may be folded to have a curvature.

Referring to FIGS. 1 and 2, in an embodiment, the display device 10 may include one folding area FDA and may be folded once. However, embodiments of the present disclosure are not limited thereto. For example, the display device 10 may include a plurality of folding areas. In this case, the display device 10 maybe folded twice or more.

In an embodiment, as shown in FIGS. 1 and 2, the folding area FDA may extend in the first direction DR1, and the display device 10 maybe folded in the second direction DR2. However, embodiments of the present disclosure are not limited thereto. For example, the folding area FDA may extend in the second direction DR2 and the display device 10 maybe folded in the first direction DR1.

In FIGS. 1 and 2, it is illustrated that the display device 10 is a foldable display; however, embodiments of the present disclosure are not limited thereto. For example, the present disclosure may be applied to manufacturing processes of various display devices, such as a slidable display, a rollable display, and the like.

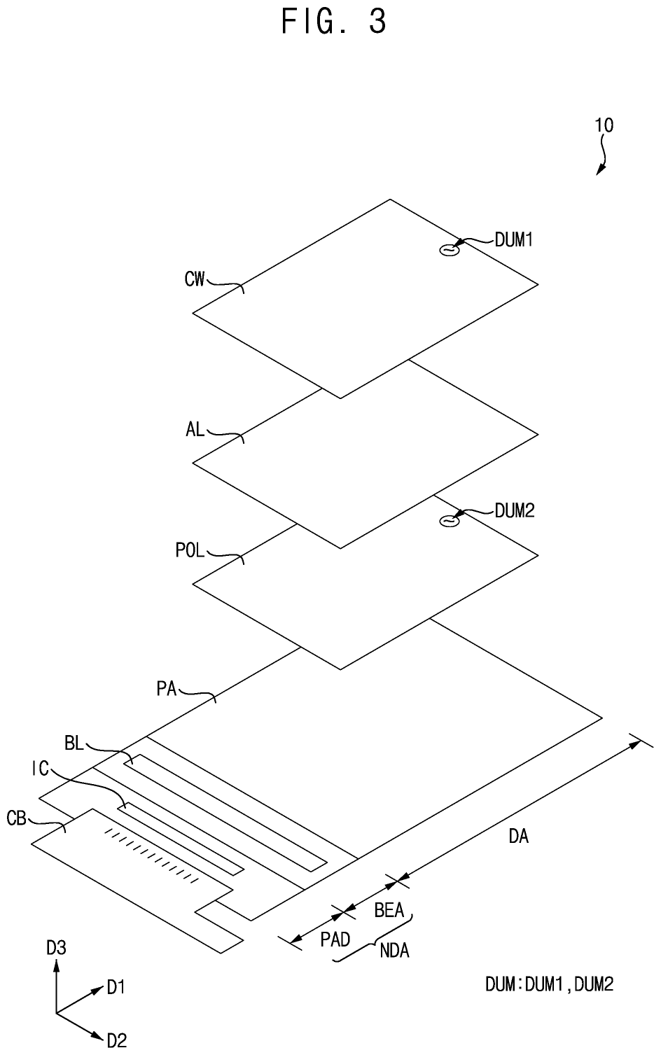

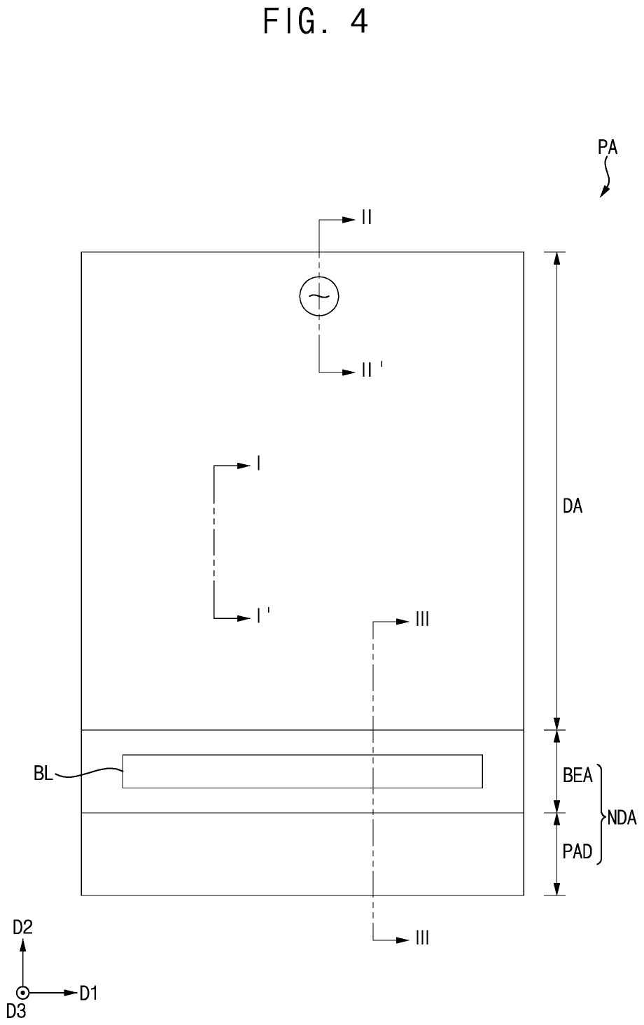

FIG. 3 is an exploded perspective view illustrating a display device according to an embodiment of the disclosure; FIG. 4 is a plan view illustrating a display panel included in the display device of FIG. 3; and FIG. 5 is a cross-sectional view illustrating the display panel included in the display device of FIG. 3.

Referring to FIGS. 3 and 4, a display device 10 may include a display panel PA, a polarization layer POL, an adhesive layer AL, a cover window CW, and a bending protection layer BL. Referring to FIG. 5, the display panel PA may include a substrate SUB, an electronic element EU, a display element DU, and a plurality of layers. The electronic element EU, the display element DU, and the plurality of layers may be disposed on the substrate SUB.

The substrate SUB may include any of various materials having flexible or bendable properties. For example, the substrate SUB may include a polymer resin. For example, the polymer resin may include any of polyether sulphone (PES), polyacrylate (PAR), polyetherimide (PEI), polyethylene naphthalate (PEN), polyethylene terephthalate (PET), polyphenylene sulfide (PPS), polyarylate (PAR), polyimide (PI), polycarbonate (PC), cellulose acetate propionate (CAP), and the like. These may be used alone or in combination with each other.

The electronic element EU may be electrically connected to the display element DU. For example, the electronic element EU may include a thin film transistor and the like. The thin film transistor may include a semiconductor layer, a gate electrode, a source electrode, and a drain electrode. The semiconductor layer may include amorphous silicon, polycrystalline silicon, an oxide semiconductor, an organic semiconductor, and the like. The gate electrode may include a low-resistance metal material. For example, the metal may include any of silver (Ag), molybdenum (Mo), aluminum (Al), copper (Cu), titanium (Ti), chromium (Cr), and the like. Each of the source electrode and the drain electrode may include the low-resistance metal material.

A gate insulating layer may be disposed between the semiconductor layer and the gate electrode. The gate insulating layer may insulate the semiconductor layer and the gate electrode. The gate insulating layer may include an inorganic material. For example, the inorganic material may include any of silicon oxide, silicon nitride, silicon oxynitride, and the like.

A planarization layer may be disposed on the electronic element EU. The planarization layer may protect the electronic device EU and may provide a flat upper surface. In an embodiment, the planarization layer may include an organic material. For example, the organic material may include any of acrylic, benzocyclobutene (BCB), hexamethyldisiloxane (HMDSO), and the like. In an embodiment, the planarization layer may be omitted.

The display element DU may be disposed on the electronic element EU. In an embodiment, the display element DU may be disposed on the planarization layer. The display element DU may emit a light with a luminance corresponding to a driving current. The lights emitted from the display element DU may be combined to display the image. For example, the display element DU may be an organic light emitting display element. The organic light emitting display element may include a first electrode, a light emitting layer, and a second electrode. The first electrode may be electrically connected to the thin film transistor. The light emitting layer may include a light emitting material. The second electrode may cover the display area DA. In an embodiment, the second electrode may cover the plurality of pixels.

In an embodiment, an encapsulation layer may be disposed on the display element DU. The encapsulation layer may protect the display element DU from moisture, oxygen, and the like. The encapsulation layer may include an inorganic material or an organic material. For example, the inorganic material may include any of silicon oxide, silicon nitride, silicon oxynitride, and the like. In an embodiment, the organic material may include any of polyethylene terephthalate (PET), polyethylene naphthalate (PEN), polycarbonate (PC), polyimide (PI), and the like. In an embodiment, the encapsulation layer may be omitted.

It has been described that the plurality of layers may include the gate insulating layer, the planarization layer, and the encapsulation layer. However, embodiments of the present disclosure are not limited thereto, and the display device 10 may further include various layers.

Referring again to FIG. 3, the polarization layer POL may be disposed on the display panel PA. The polarization layer POL may reduce reflection of an external light. For example, the external light may pass through the polarization layer POL so as to be reflected from a top surface of the second electrode. A phase of the light reflected from the top surface of the second electrode may be inverted while the light passes through the polarization layer POL. Accordingly, the external light and the reflected light may cause destructive interference, such that visibility may be improved. In an embodiment, the polarization layer POL may be omitted. For example, the reflection of the external light may be reduced by using a black material and a color filter instead of the polarization layer POL. In an embodiment, the polarization layer POL may include polyvinyl alcohol (PVA).

The adhesive layer AL may be disposed on the polarization layer POL. The adhesive layer AL may include a material having adhesive strength. In an embodiment, the adhesive layer AL may include a pressure sensitive adhesive (PSA).

The cover window CW may be disposed on the adhesive layer AL. The cover window CW may include a material having high strength and transparency. For example, the cover window CW may include any of a glass, a polyimide, and the like.

Referring again to FIG. 4, the display panel PA may include the display area DA and the non-display area NDA. The non-display area NDA may include a bending area BEA and a pad area PAD.

The pad area PAD may be spaced apart from the display area DA. The pad area PAD may overlap a portion of a circuit board CB.

The bending area BEA may be located between the display area DA and the pad area PAD. The bending area BEA may have a curvature.

The bending protection layer BL may be disposed on the bending area BEA. When the bending area BEA is bent, stress may be applied to the bending area BEA. Accordingly, a crack or the like may be generated in the bending area BEA. When the crack is propagated, a dark spot or the like may be generated in the display device 10. In order to prevent or substantially prevent the dark spot or the like from being generated, the display device 10 may further include the bending protection layer BL. The bending protection layer BL may include an organic material capable of absorbing the stress.

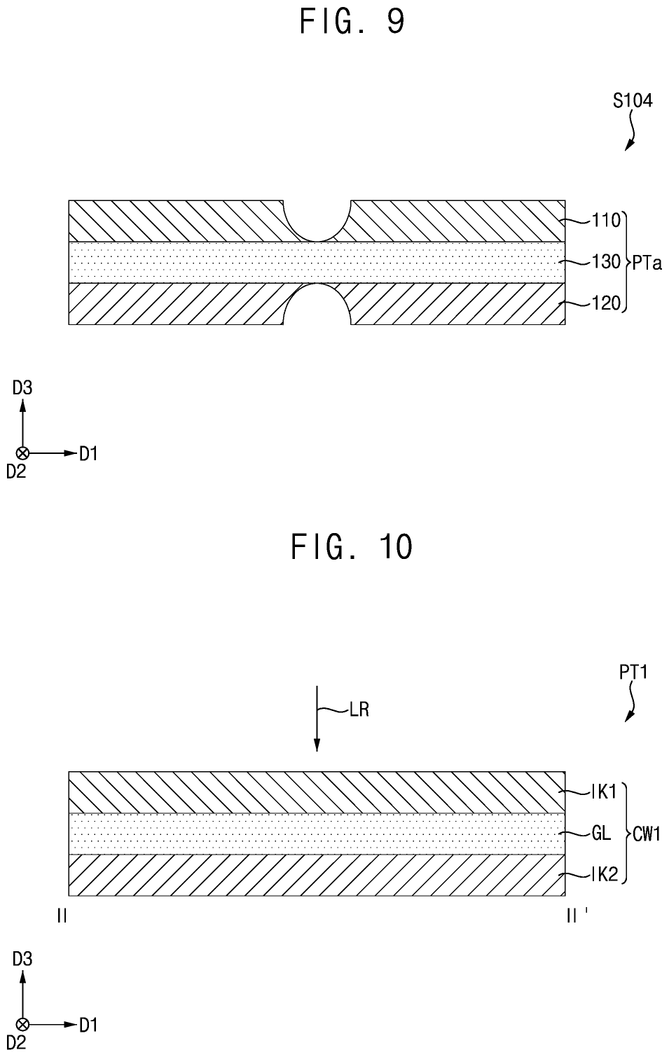

FIGS. 6 to 13 are cross-sectional views illustrating a method of manufacturing a display device according to an embodiment of the disclosure.

Referring to FIG. 6, a processing target PTa having a multi-layer structure including multiple layers having mutually different optical properties may be prepared (S102).

When the multi-layer structure including the multiple layers having the mutually different optical properties is included in the display device, upon processing performed with a laser beam, diffraction of a light wave may occur at an interface of the layers. Accordingly, after an upper layer is processed by the laser beam, when a lower layer disposed under the upper layer is processed, a processing speed may be reduced, a processing shape may be changed, or processing properties may be changed.

In an embodiment, the processing target PTa may include a first layer 110, a second layer 120, and a third layer 130. An absorptance of the third layer 130 may be smaller than an absorptance of the first layer 110 and an absorptance of the second layer 120.

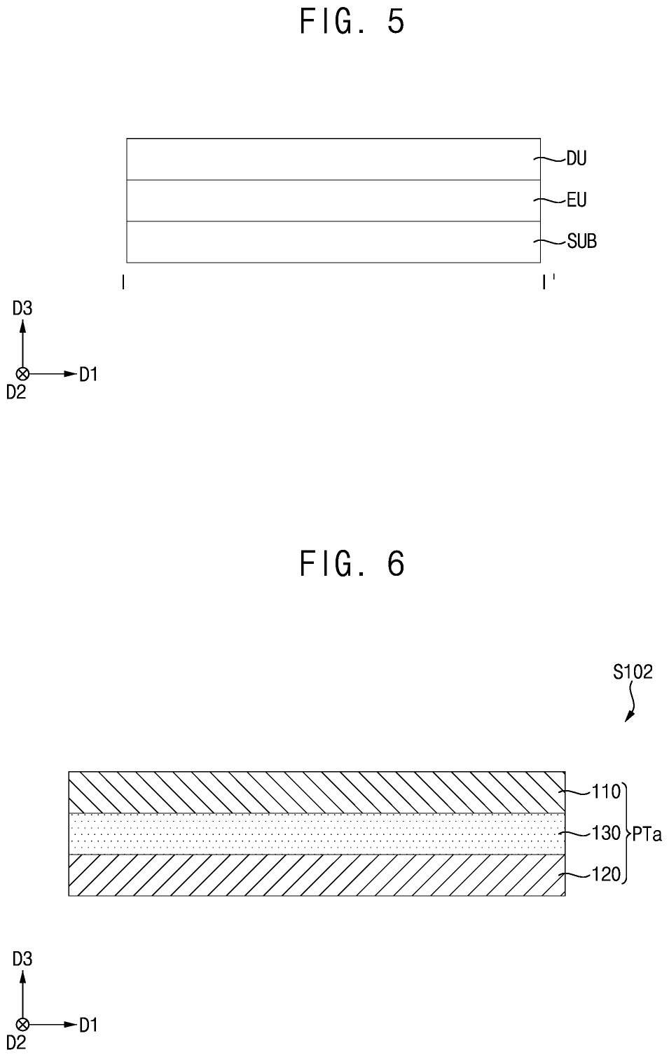

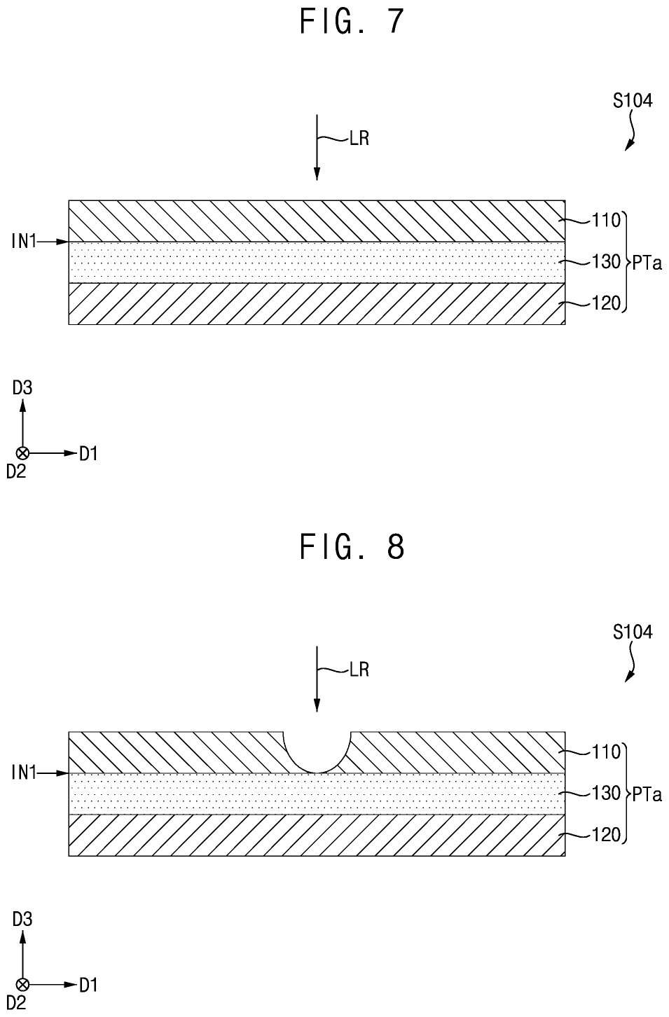

The absorptance may refer to an absorptance of energy of a laser beam (e.g., a laser beam LR of FIG. 7) irradiated to the processing target PTa. The absorptance may be associated with a processing depth. For example, as the absorptance increases, the processing depth caused by the laser beam may be gradually increased.

Referring to FIGS. 7, 8, and 9, the laser beam LR may be irradiated to the processing target PTa. The processing target PTa may be processed by the laser beam LR (S104).

In an embodiment, the laser beam LR may be an ultrashort-wave pulsed laser beam. Processing quality of the ultrashort-wave pulsed laser beam may be superior to processing quality of a heat-based laser beam (e.g., a CO₂ laser). For example, when the cutting process is performed with the ultrashort-wave pulsed laser beam, an amount of carbonized foreign substances generated may be reduced by about 78% as compared with a case in which the cutting process is performed with the heat-based laser beam.

In an embodiment, the pulsed laser beam may have a pulse width of a nanosecond (ns) scale or less. For example, the pulsed laser beam may be a nanosecond pulsed laser, a picosecond pulsed laser, or a femtosecond pulsed laser. Accordingly, a heat transfer portion of the processing target PTa may be minimized or reduced. Therefore, a heat-affected zone (HAZ) at a periphery of the heat transfer portion may be minimized or reduced, and processing quality of the display device may be improved.

In an embodiment, the laser beam LR may sequentially remove the first layer 110 and the second layer 120. For example, the laser beam LR may be irradiated toward the first layer 110. The first layer 110 and the second layer 120 may be removed by the laser beam LR, whereas the third layer 130 may be preserved without being removed. After processing is performed by the laser beam LR, optical properties of the third layer 130 may not be substantially changed. For example, transmittances of the third layer 130 before and after the processing may be substantially the same or similar to each other.

In an embodiment, each of the absorptance of the first layer 110 and the absorptance of the second layer 120 may be greater than or equal to about 5%, and the absorptance of the third layer 130 may be less than or equal to about 0.5%. When each of the absorptance of the first layer 110 and the absorptance of the second layer 120 is less than about 5%, or the absorptance of the third layer 130 is greater than about 0.5%, the third layer 130 may also be processed. Therefore, in an embodiment, in order to perform processing that allows the third layer 130 to be preserved, each of the absorptance of the first layer 110 and the absorptance of the second layer 120 may be greater than or equal to about 5%, and the absorptance of the third layer 130 may be less than or equal to about 0.5%.

Although the multi-layer structure including three layers has been illustrated in FIGS. 6 to 9, embodiments of the present disclosure are not limited thereto. For example, the multi-layer structure may include four layers or more. In this case, the laser beam LR may perform processing that processes only an uppermost layer and a lowermost layer and allows layers between the uppermost layer and the lowermost layer to be preserved.

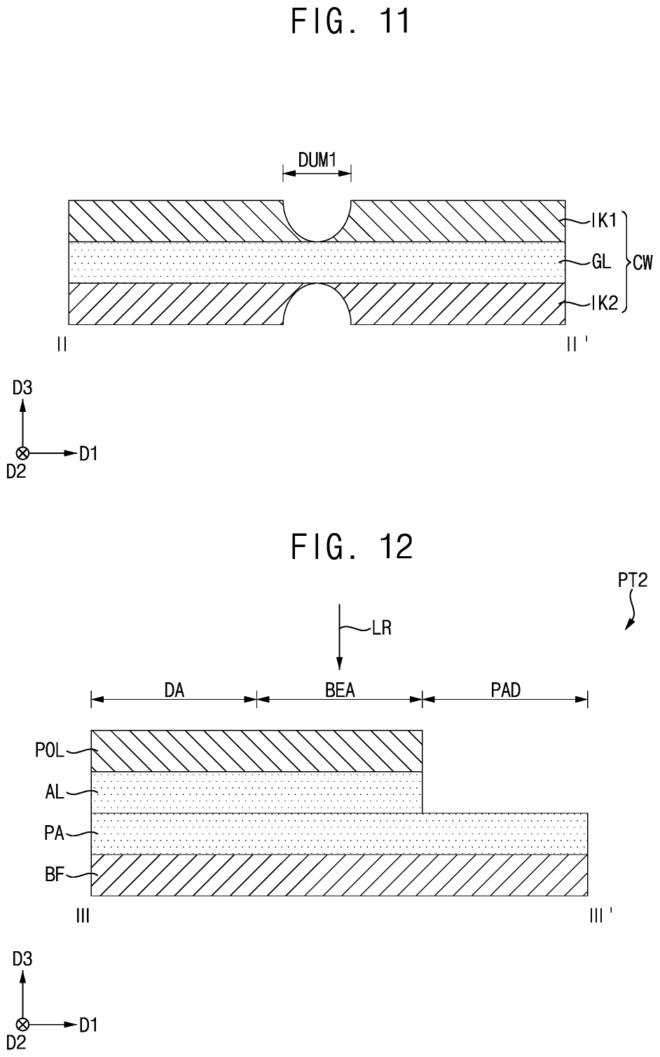

Referring to FIGS. 10 and 11, the cover window CW may be formed by the method of manufacturing the display device.

In an embodiment, the processing target PT1 may include a first layer IK1, a second layer IK2, and a third layer GL. In an embodiment, each of the first layer IK1 and the second layer IK2 may include a colored ink. The third layer GL may include a glass.

First, the third layer GL including the glass may be prepared. Next, the first layer IK1 and the second layer IK2 including the colored ink may be formed on upper and lower portions of the third layer GL.

The first layer IK1 and the second layer IK2 may be sequentially removed by irradiating the laser beam LR to the processing target PT1. In an embodiment, only a portion of the colored ink included in the first layer IK1 and the second layer IK2 may be selectively removed by irradiating the laser beam LR.

An absorptance of the glass may be smaller than an absorptance of the colored ink. Therefore, the laser beam LR may remove the colored ink included in the first layer IK1. Next, the laser beam LR may pass through the third layer GL so as to remove the colored ink included in the second layer IK2. In this process, optical properties of the third layer GL may be preserved. For example, the absorptance of the third layer GL may not be changed. Accordingly, a color of the glass may not be substantially changed.

Accordingly, the cover window CW from which the colored ink is removed in a dummy area DUM1 may be fabricated. The dummy area DUM1 may correspond to the dummy area DUM1 of FIGS. 3 and 4. Specifically, the dummy area DUM1 may be an area at a position overlapping a camera hole (e.g., the dummy area DUM1 of FIGS. 3 and 4).

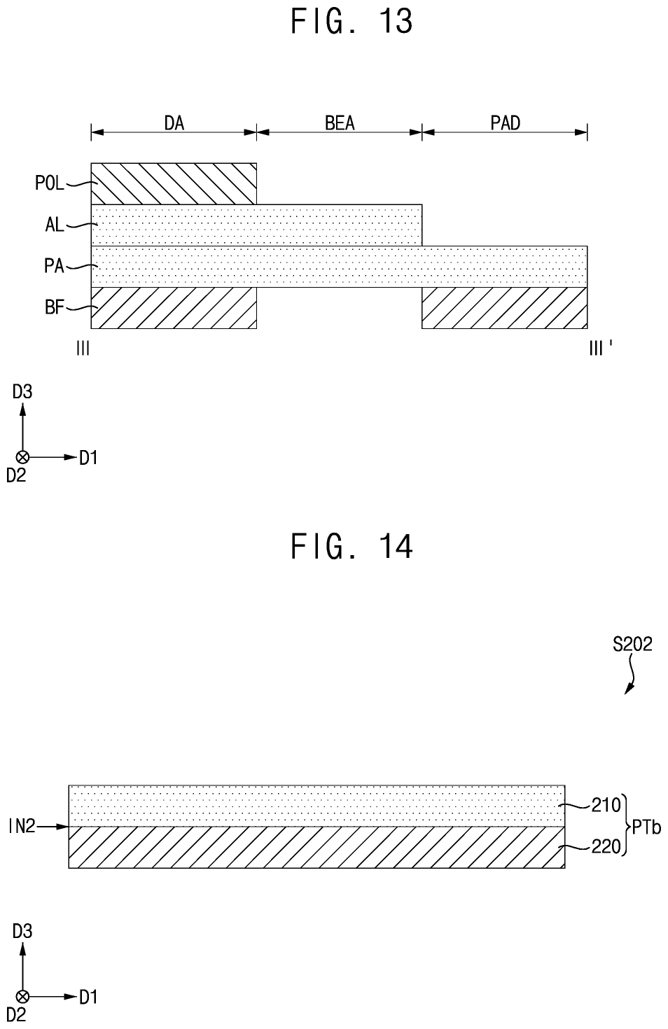

Referring to FIGS. 12 and 13, the bending protection layer BL may be formed by the method of manufacturing the display device.

In an embodiment, a processing target PT2 may include a first layer including a polarization layer POL, a third layer including the display panel PA and the adhesive layer AL, and a second layer including the lower protective film BF.

First, the display panel PA including the display area DA, the pad area PAD spaced apart from the display area DA, and the bending area BEA located between the display area DA and the pad area PAD and having a curvature may be formed. In an embodiment, the display panel PA may be formed on a substrate (e.g., the substrate SUB of FIG. 5) including polyimide. Next, the adhesive layer AL may be formed on the display panel PA. In an embodiment, the adhesive layer AL may be formed of a pressure-sensitive adhesive (PSA).

Next, the polarization layer POL may be formed on the adhesive layer AL.

In an embodiment, the polarization layer POL may be formed of a polyvinyl alcohol (PVA).

In an embodiment, the lower protective film BF may be formed under the display panel PA, and the lower protective film BF may be formed of polyethylene terephthalate (PET).

The first layer and the second layer may be sequentially removed by irradiating the laser beam LR to the processing target PT2. A portion of the polarization layer POL and a portion of the lower protective film BF may be selectively removed by irradiating the laser beam LR.

Each of an absorptance of the display panel PA and an absorptance of the adhesive layer AL may be smaller than an absorptance of the polarization layer POL. In addition, each of the absorptance of the display panel PA and the absorptance of the adhesive layer AL may be smaller than an absorptance of the lower protective film BF. Therefore, the laser beam LR may remove the portion of the polarization layer POL which overlaps the bending area BEA of the display panel PA. Next, the laser beam LR may pass through the display panel PA and the adhesive layer AL so as to remove the lower protective film BF. The laser beam LR may remove the lower protective film BF overlapping the bending area BEA of the display panel PA. In this process, optical properties of the display panel PA and the adhesive layer AL may be preserved. For example, the absorbance's of the display panel PA and the adhesive layer AL may not be changed.

Accordingly, a thickness of the bending area BEA in a cross-sectional view may be reduced with one process. Therefore, the stress applied to the display device (e.g., the display device 10 shown in FIGS. 3 and 4) may be reduced. In the above process, a remaining resin (e.g., a portion of the adhesive layer AL overlapping the bending area BEA) may serve as the bending protection layer BL. Accordingly, a separate process of forming the bending protection layer BL may be omitted in the method of manufacturing the display device according to the present disclosure.

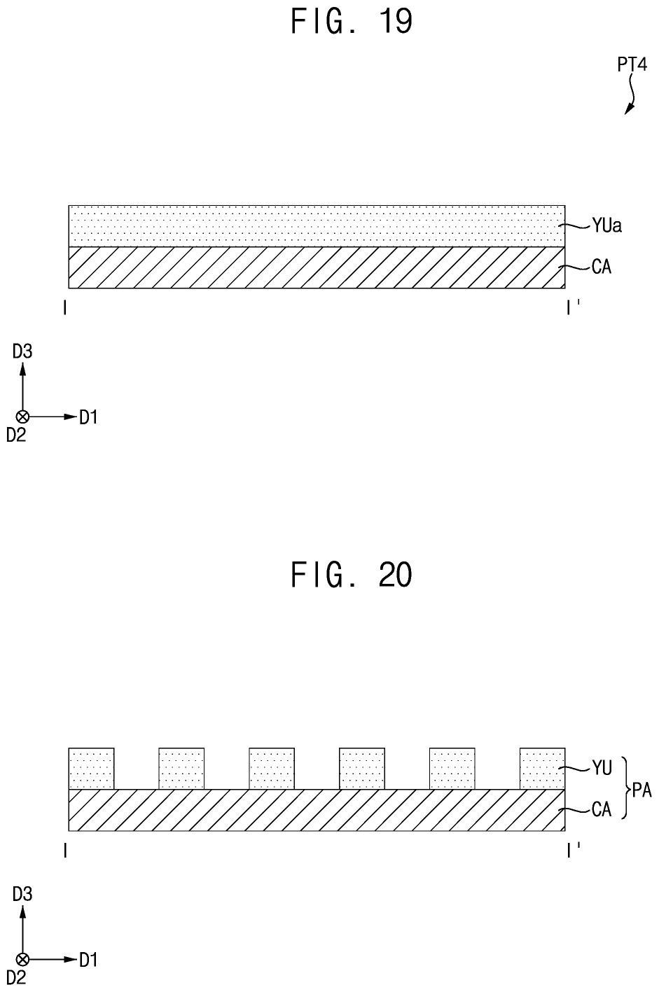

FIGS. 14 to 22 are cross-sectional views illustrating a method of manufacturing a display device according to another embodiment of the disclosure.

Herein, descriptions overlapping with the method of manufacturing the display device described above with reference to FIGS. 1 to 13 maybe omitted or simplified.

Referring to FIG. 14, a processing target PTb having a multi-layer structure including multiple layers having mutually different optical properties may be prepared (S202).

The processing target PTb may include a first layer 210 and a second layer 220. A refractive index of the second layer 220 may be greater than a refractive index of the first layer 210.

The refractive index may refer to a refractive index of each of the layers included in the processing target PTb. The refractive index may be associated with a processing speed. For example, when the laser beam LR is irradiated, the processing speed may be reduced at an interface between a layer having a low refractive index and a layer having a high refractive index. In other words, processing that allows the layer having the high refractive index to be preserved may be performed by arranging a layer having a relatively high refractive index under a layer having a relatively low refractive index.

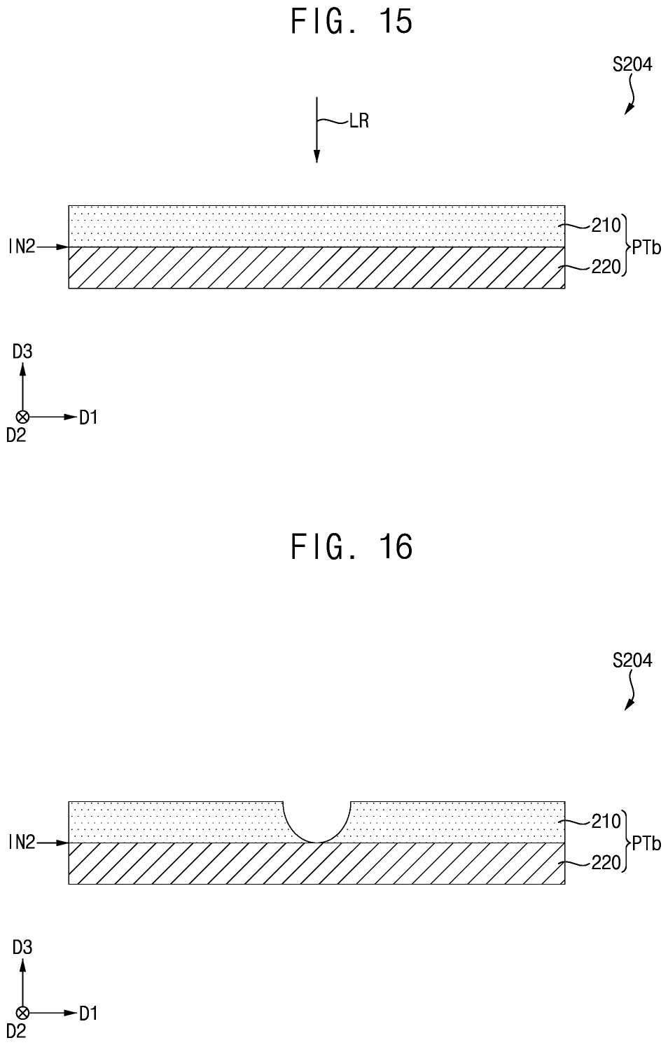

Referring to FIGS. 15 and 16, the laser beam LR may be irradiated to the processing target PTb (S204).

In an embodiment, the laser beam LR may selectively process only the first layer 210. In this case, the processing may be performed while preserving optical properties of the second layer 220. For example, the optical properties may include a transmittance.

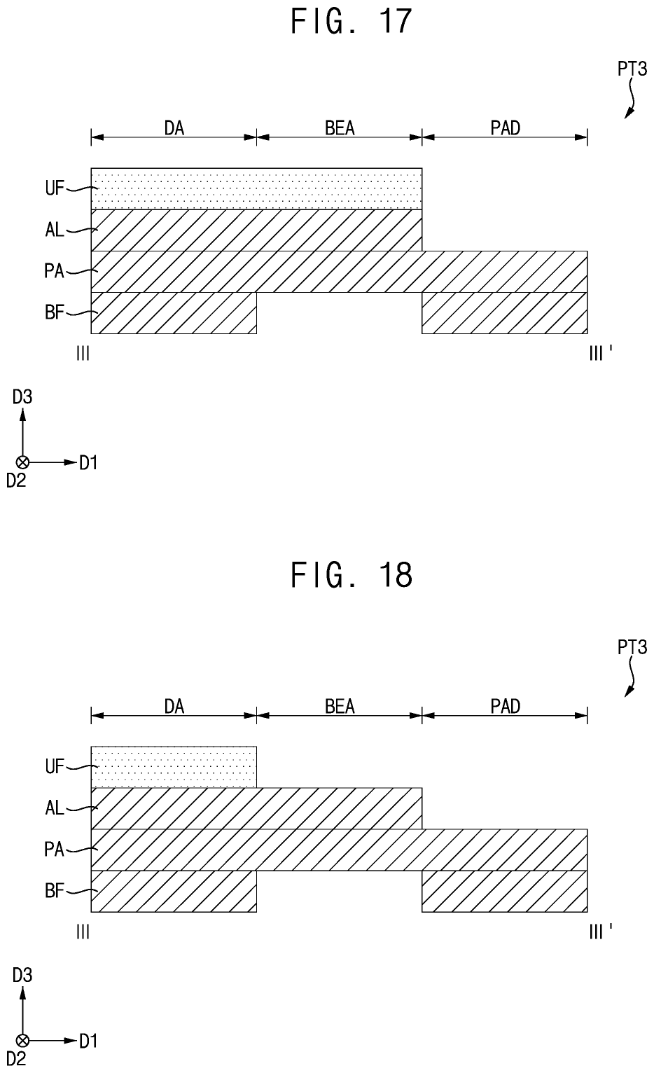

Referring to FIGS. 17 and 18, an upper protective film UF may be removed by the method of manufacturing the display device.

In an embodiment, a processing target PT3 may include a first layer including the upper protective film UF and a second layer including the adhesive layer AL. The upper protective film BF may be formed of polyethylene terephthalate (PET), and the adhesive layer AL may be formed of a pressure sensitive adhesive (PSA).

First, the first layer including the upper protective film UF may be formed on the second layer including the adhesive layer AL. A refractive index of the adhesive layer AL may be greater than a refractive index of the upper protective film UF.

Only the first layer may be selectively processed by irradiating the laser beam LR to the processing target PT3. In an embodiment, a portion of the upper protective film UF overlapping the bending area BEA of the display panel PA may be removed by irradiating the laser beam LR. In this process, the optical properties of the display panel PA and the adhesive layer AL may be preserved. For example, the absorbance's of the display panel PA and the adhesive layer AL may not be changed.

Accordingly, the thickness of the bending area BEA in the cross-sectional view may be reduced through a process of half-cutting the lower protective film BF and a process of removing the portion of the upper protective film UF. Therefore, the stress applied to the display device may be reduced. In addition, in the process, the remaining resin (e.g., the portion of the adhesive layer AL overlapping the bending area BEA) may serve as the bending protection layer BL. Accordingly, the process of forming the bending protection layer BL may be omitted in the method of manufacturing the display device.

Referring to FIGS. 1, 19, and 20, a patterning process of a layer included in the display panel PA may be performed by the method of manufacturing the display device.

In an embodiment, a processing target PT4 may include a second layer CA including a metal and a first preliminary layer YUa including a polymer compound. The first preliminary layer YUa may have a plate shape. A refractive index of the second layer CA may be greater than a refractive index of the first preliminary layer YUa.

Next, only the first preliminary layer YUa may be selectively processed by irradiating the laser beam LR to the processing target PT4. In an embodiment, a first layer YU having a concavo-convex shape may be formed by irradiating the laser beam LR.

For example, according to the foldable display device, stress may be accumulated in the folding area FDA. Accordingly, a crack may be generated in the folding area FDA. In order to prevent or substantially prevent the crack from being generated, the stress may be alleviated by forming a lattice shape. The lattice shape may be formed by irradiating the laser beam LR to the first preliminary layer YUa.

For example, the second layer CA may be formed of any of silver (Ag), molybdenum (Mo), copper (Cu), aluminum (Al), titanium (Ti), chromium (Cr), and the like. The first preliminary layer YUa may be formed of any of polyimide (PI), polyethylene terephthalate (PET), silicon oxide (SiOx), and the like.

When the patterning process using the laser according to an embodiment of the disclosure is used, a cost may be reduced as compared with a case in which the lattice shape is formed by a photolithography process.

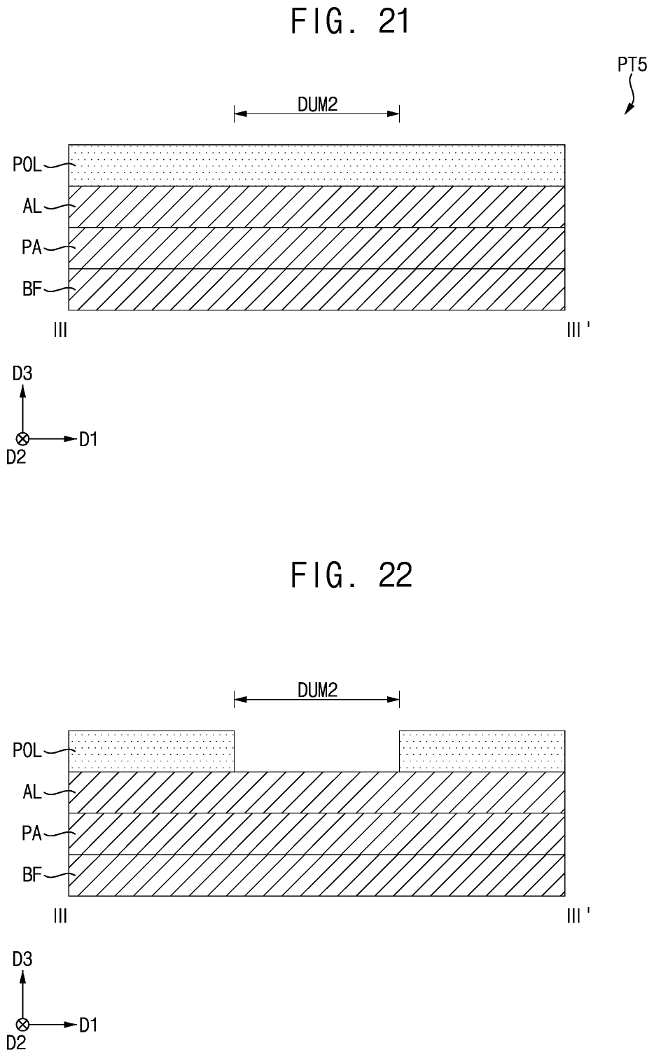

Referring to FIGS. 21 and 22, the bending protection layer BL may be formed by the method of manufacturing the display device.

In an embodiment, a processing target PT5 may include a first layer including the polarization layer POL and a second layer including the lower protective film BF and the adhesive layer AL.

First, the display panel PA including the display area DA, the pad area PAD spaced apart from the display area DA, and the bending area BEA located between the display area DA and the pad area PAD and having a curvature may be formed. In an embodiment, the display panel PA may be formed on the substrate (e.g., the substrate SUB of FIG. 5) including polyimide. Next, the adhesive layer AL may be formed on the display panel PA. The adhesive layer AL may be formed of a pressure-sensitive adhesive (PSA). Next, the polarization layer POL may be formed on the adhesive layer AL. The polarization layer POL may be formed of polyvinyl alcohol (PVA). In an embodiment, the lower protective film BF may be formed under the display panel PA, and the lower protective film BF may be formed of polyethylene terephthalate (PET).

Only the first layer may be selectively processed by irradiating the laser beam LR to the processing target PT5. In further detail, only the portion of the polarization layer POL may be selectively removed by irradiating the laser beam LR. Each of the refractive index of the adhesive layer AL, the refractive index of the display panel PA, and the refractive index of the lower protective film BF may be greater than the refractive index of the polarization layer POL. Accordingly, only the portion of the polarization layer POL may be removed in a dummy area DUM2.

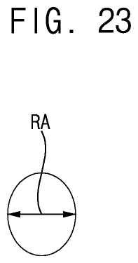

FIG. 23 is a view illustrating a method of manufacturing a display device according to another embodiment of the disclosure.

Referring to FIG. 23, interfacial adhesive forces of the processing targets PTa or PTb having the multi-layer structure including the multiple layers having the mutually different optical properties may be adjusted by adjusting a beam diameter RA of the laser beam (e.g., the laser beam LR of FIG. 7 or the laser beam LR of FIG. 15).

In an embodiment, when the laser beam having a first diameter is irradiated to the processing target, the interfacial adhesive force (e.g., a first interface IN1 of FIG. 7 or a second interface IN2 of FIG. 14) between a first layer (e.g., the second layer 120 of FIG. 7 or the first layer 210 of FIG. 14) and a second layer (e.g., the third layer 130 of FIG. 7 or the second layer 220 of FIG. 14) may be a first adhesive force. When the laser beam having a second diameter that is smaller than the first diameter is irradiated to the processing target, the interfacial adhesive force between the first layer and the second layer may be a second adhesive force. The laser beam having the second diameter may have higher energy density than the laser beam having the first diameter. Accordingly, the second adhesive force may be greater than the first adhesive force. In an embodiment, the diameter of the laser beam may be reduced by using a lens having a small focus.

For example, when the laser beam has a diameter RA of about 40 micrometers or more, the laser beam may be used to form a layer requiring delamination and the like.

Although a case in which the interfacial adhesive force is increased by reducing the diameter RA of the laser beam has been illustrated above, embodiments of the present disclosure are not limited thereto. For example, the interfacial adhesive force may be reduced by increasing the diameter RA of the laser beam. The diameter of the laser beam may be increased by using a lens having a large focal length.

For example, when the laser beam has the diameter RA of about 37 square micrometers or less, the laser beam may be used to form a capping layer and the like that serves as waterproofing.

The method of manufacturing the display device according to embodiments of the present disclosure may be applied to a display device included in a computer, a notebook, a mobile phone, a smartphone, a smart pad, a PMP, a PDA, an MP3 player, a mobile body, or the like.

Although methods and systems according to some embodiments have been described with reference to the drawings, the illustrated embodiments are provided as non-limiting examples, and may be modified and changed by a person having ordinary knowledge in the relevant technical field without departing from the technical spirit described in the claims.

What is claimed is:

1. A method of manufacturing a display device, the method comprising:
preparing a processing target including a first layer, a second layer, and a third layer located between the first layer and the second layer and having an absorptance that is smaller than each of an absorptance of the first layer and an absorptance of the second layer; and
sequentially removing the first layer and the second layer by irradiating a pulsed laser beam to the processing target.

2. The method of claim 1, wherein the preparing the processing target comprises:
preparing the third layer comprising a glass; and
forming the first layer and the second layer each comprising a colored ink on upper and lower portions of the third layer.

3. The method of claim 2, wherein the sequentially removing the first layer and the second layer comprises selectively removing a portion of the colored ink of the first layer and the second layer by using the pulsed laser beam.

4. The method of claim 1, wherein the preparing the processing target comprises:
forming the third layer comprising a display panel including a display area, a pad area spaced apart from the display area, and a bending area located between the display area and the pad area, and an adhesive layer on the display panel;
forming the first layer comprising a polarization layer on the third layer; and
forming the second layer comprising a lower protective film under the third layer.

5. The method of claim 4, wherein the sequentially removing the first layer and the second layer comprises selectively removing only a portion of the polarization layer and a portion of the lower protective film which overlap the bending area of the display panel by using the pulsed laser beam.

6. The method of claim 4, wherein
the display panel is formed on a substrate comprising polyimide,
the adhesive layer is formed of a pressure-sensitive adhesive,
the polarization layer is formed of polyvinyl alcohol, and
the lower protective film is formed of polyethylene terephthalate.

7. The method of claim 1, wherein the pulsed laser beam has a pulse width of nanosecond scale or less.

8. The method of claim 1, wherein
each of the absorptance of the first layer and the absorptance of the second layer is greater than or equal to about 5 percent, and
the absorptance of the third layer is less than or equal to about 0.5 percent.

9. A method of manufacturing a display device, the method comprising:
preparing a processing target including a first layer and a second layer located under the first layer and having a refractive index that is greater than a refractive index of the first layer; and
processing the first layer by irradiating a pulsed laser beam having a pulse width of nanosecond scale or less to the processing target.

10. The method of claim 9, wherein the preparing the processing target comprises:
forming the second layer comprising a display panel including a display area, a pad area spaced apart from the display area, and a bending area located between the display area and the pad area, and an adhesive layer on the display panel; and
forming the first layer comprising an upper protective film on the second layer.

11. The method of claim 10, wherein the processing the first layer comprises selectively removing only a portion of the upper protective film which overlaps the bending area of the display panel by using the pulsed laser beam.

12. The method of claim 10, wherein
the display panel is formed on a substrate comprising polyimide,
the adhesive layer is formed of a pressure-sensitive adhesive, and
the upper protective film is formed of polyethylene terephthalate.

13. The method of claim 9, wherein the preparing the processing target comprises:
forming the second layer comprising a metal; and
forming a first preliminary layer comprising a polymer compound and having a plate shape.

14. The method of claim 13, wherein the processing the first layer comprises forming a concavo-convex shape by irradiating the pulsed laser beam to the first preliminary layer.

15. The method of claim 13, wherein the metal comprises at least one selected from the group consisting of silver, molybdenum, copper, aluminum, titanium, and chromium, and
the polymer compound comprises at least one selected from the group consisting of polyimide, polyethylene terephthalate, and silicon oxide.

16. The method of claim 9, wherein the preparing the processing target comprises:
forming the second layer comprising a display panel including a display area, a pad area spaced apart from the display area, and a bending area located between the display area and the pad area, and an adhesive layer on the display panel; and
forming the first layer comprising a polarization layer on the second layer.

17. The method of claim 10, wherein the processing the first layer comprises selectively removing only a portion of the polarization layer which overlaps the bending area of the display panel by using the pulsed laser beam.

18. The method of claim 10, wherein
the display panel is formed on a substrate comprising polyimide,
the adhesive layer is formed of a pressure-sensitive adhesive, and
the polarization layer is formed of polyvinyl alcohol.
